(19) United States
(12) Patent Application Publication
(10) Pub. No.: US 2008/0197509 A1
(43) Pub. Date: Aug. 21, 2008

(54) Semiconductor package having stacked semiconductor chips

(75) Inventors: Masahiro Yamaguchi, Tokyo (JP); Masanori Shibamoto, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/068,485

(22) Filed: Feb. 7, 2008

(30) Foreign Application Priority Data
Feb. 15, 2007 (JP) 2007-034625

(51) Int. Cl. H01L 23/49

(52) U.S. Cl. 257/777; 257/784; 257/E23.024

(57) ABSTRACT

A semiconductor package including: a package substrate on the surface of which plural connection terminals are provided; a semiconductor chip on the surface of which plural bonding pads are provided; plural bonding wires that connect between the plural connection terminals and the plural bonding pads; a resin formed to fill a gap between the bonding wires and the surface of the semiconductor chip; and a semiconductor chip provided on the bonding wires via a film-shaped resin, wherein at least three of the plural bonding wires are formed at substantially the same heights and higher than other bonding wires.

### TECHNICAL FIELD

The present invention relates to a semiconductor package, and particularly, relates to a configuration of a semiconductor package having stacked semiconductor chips.

### BACKGROUND OF THE INVENTION

In a semiconductor device, particularly, in a DRAM (Dynamic Random Access Memory), a package having stacked semiconductor chips (bare chips), what is called a DDP (Dual Die Package), is used to enlarge memory size.

A bare chip of the DRAM generally has a center pad configuration having plural boding pads laid out in the center area of a chip surface. Therefore, boding using a long wire is necessary for electrical connection with a package substrate and the bare chip

However, when a first-layer semiconductor chip is connected to a package substrate and then a second-layer semiconductor chip is stacked on the first-layer semiconductor chip using plural bonding wires, the following problems occur due to a variation in the height of a long wire. That is, at the time of mounting the second-layer semiconductor chip on the plural bonding wires, it becomes difficult to horizontally mount the second-layer semiconductor chip in good balance. Therefore, large load is applied to a part of the semiconductor chip, and the surface of the first-layer semiconductor chip is brought into contact with the bonding wires.

When the second-layer semiconductor chip is mounted with an inclination, the pressure is concentrated to a part of the second-layer semiconductor chip at the time of bonding the second-layer semiconductor chip. Therefore, this causes a risk that first-layer bonding wires are pressed down and are brought into contact with the first-layer semiconductor chip.

To solve this problem, there has been proposed a technique of laying out a line-state supporting structure along a surface facing the first-layer semiconductor chip, or laying out a separated mound-shaped supporting structure on a corner of the first-layer semiconductor chip, and supporting the second-layer semiconductor chip with this supporting structure (Japanese Patent Application Laid-open No. 2004-312008).

However, according to the method disclosed in Japanese Patent Application Laid-open No. 2004-312008, the supporting structure is laid out in a line state along the surface facing the first-layer semiconductor chip, or is laid out in a separated mound shape on the corner of the first-layer semiconductor chip, as described above. Therefore, an electrode pad (a bonding pad) cannot be formed at the position where the supporting structure is laid out.

Among semiconductor chips of a center-pad configuration, electrode pads for power supply or for grounding are often laid out around the semiconductor chip. Therefore, according to the technique disclosed in the patent document, the supporting structure becomes a hindrance of the layout of the electrode pad, and the degree of freedom of the layout of the electrode pads decreases.

The method disclosed in the patent document also requires materials and processes to form the supporting structure. Therefore it results in cost increase. Incidentally, semiconductor packages using bonding wires are also described in, for example, Japanese Patent Application Laid-open No. 2003-163314, Japanese Patent Application Laid-open No. 2002-43357 and U.S. Pat. No. 6,472,758.

### SUMMARY OF THE INVENTION

The present invention has been achieved in view of the light of the above problems, and an object of the present invention is to provide a semiconductor package having stacked semiconductor chips capable of preventing bonding failures without decreasing the degree of freedom of the layout of the electrode pads and without increasing a special manufacturing process.

The semiconductor package according to the present invention includes: a package substrate on the surface of which a plurality of connection terminals are provided; a first semiconductor chip on the surface of which a plurality of bonding pads are provided; a plurality of bonding wires that connect between the plurality of connection terminals and the plurality of bonding pads, respectively; a first resin formed to fill a gap between the plurality of bonding wires and the surface of the first semiconductor chip; and a second semiconductor chip provided on the plurality of bonding wires via a film-shaped second resin, wherein at least three of the plurality of bonding wires have substantially the same height and are higher than other bonding wires.

As explained above, according to the present invention, at least three bonding wires are formed at substantially the same height and also higher than other bonding wires on the first semiconductor chip. Therefore, the at least three bonding wires can support the second semiconductor chip. Consequently, at the time of mounting the second semiconductor chip, the bonding wires on the first semiconductor chip can be prevented from being in contact with the upper surface of the first semiconductor chip.

Therefore, the supporting structure as described in Japanese Patent Application Laid-open No. 2004-312008 becomes unnecessary. In addition, the bonding pads (electrode pads) can be freely laid out not only in the center area of the first semiconductor chip but also in the peripheral area.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a top plan view for explaining a configuration of a semiconductor package according to one embodiment of the present invention;

FIG. 2 is a side view of the state of FIG. 1 viewed from a direction of an arrowhead C;

FIGS. 3A and 3B are partially cross-sectional views of FIG. 1; FIG. 3A is a cross-sectional view along a line A-A; and FIG. 3B is a cross-sectional view along a line B-B;

FIGS. 4A and 4B are partial cross-sectional views for explaining a process (formation of a liquid resin 103) to form a semiconductor package according to the embodiment;

FIGS. 5A and 5B are partial cross-sectional views for explaining a process (mounting of a semiconductor chip 200 and formation of bonding wires 202) to form a semiconductor package according to the embodiment;

FIGS. 6A and 6B are partial cross-sectional views for explaining a process (molding of a mold resin 300) to form a semiconductor package according to the embodiment; and

FIG. 7 is a plan view for explaining another embodiment of the present invention.

### DETAILED DESCRIPTION OF THE EMBODIMENTS

Preferred embodiments of the present invention will be explained below in detail with reference to the accompanying drawings.

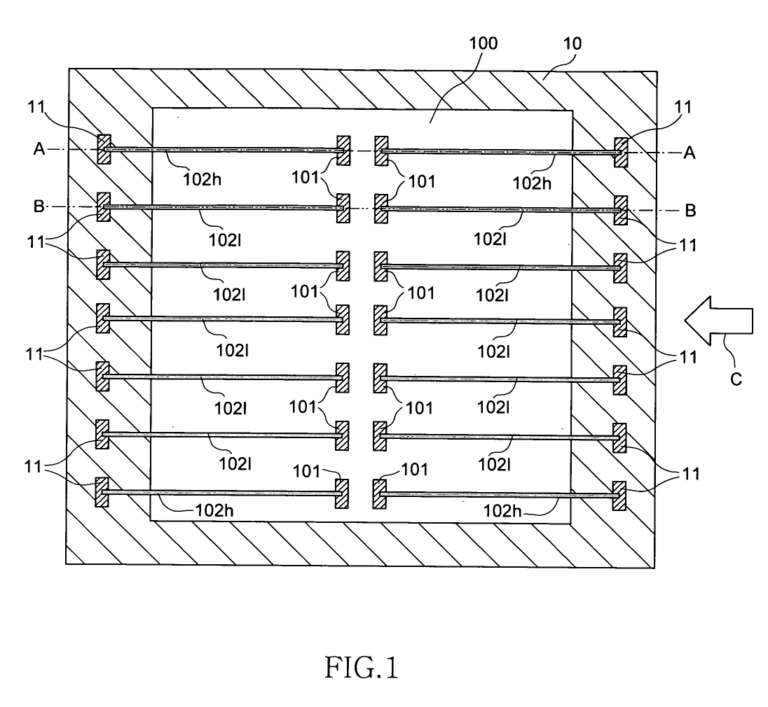

FIG. 1 is a top plan view for explaining a configuration of a semiconductor package according to one embodiment of the present invention, and shows a state after wire bonding is performed on a first-layer semiconductor chip 100.

As shown in FIG. 1, plural connection terminals 11 are arranged linearly at both sides of a package substrate 10.

The first-layer semiconductor chip 100 is mounted on the package substrate 10. Plural boding pads (center pads) 101 are laid out in two rows in the center area of the surface of the semiconductor chip 100.

With plural bonding wires 102h and 102l, the bonding pads arranged at the right side of the center pads 101 are connected to the connection terminals 11 provided at the right side of the package substrate 10, respectively. Also, the bonding pads arranged at the left side of the center pads 101 are connected to the connection terminals 11 provided at the left side of the package substrate 10, respectively.

Among the plural bonding wires, four bonding wires 102h close to the corners of the semiconductor chip 100 are formed higher than the other bonding wires 102l. Instead of dummy wires, wires actually electrically used can be used for the bonding wires 102h. Therefore, dummy bonding pads or dummy connection terminals are not necessary, and the surfaces of the semiconductor chip 100 and the package substrate 10 can be used effectively.

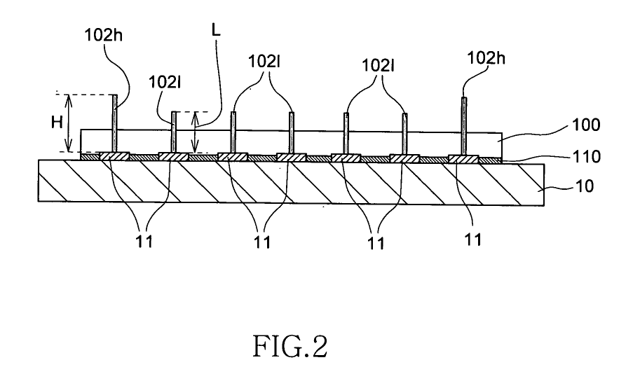

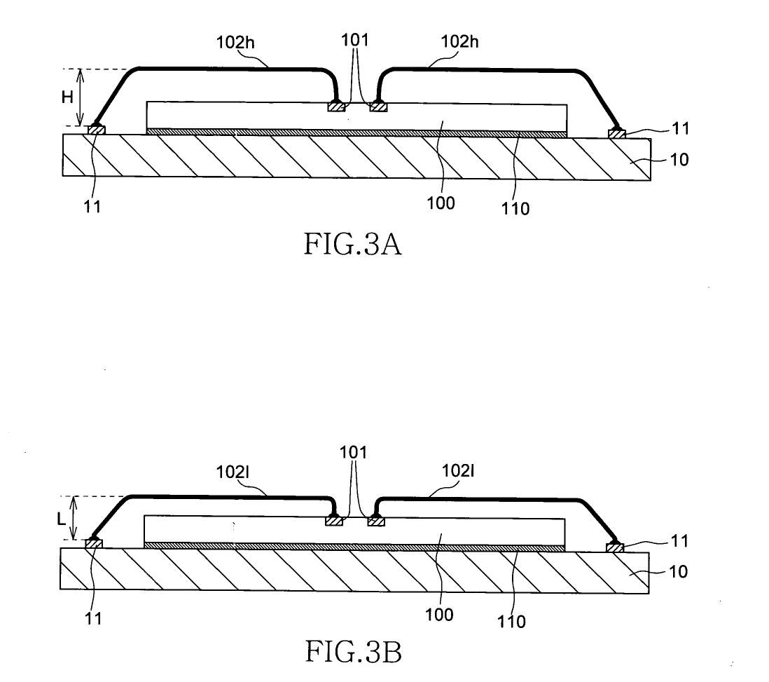

The top plan view of FIG. 1 does not show a difference between the heights of the bonding wires 102h and those of the bonding wires 102l. Therefore, this difference is explained with reference to FIG. 2 and FIG. 3.

FIG. 2 is a side view of the state of FIG. 1 viewed from a direction of an arrowhead C.

As shown in FIG. 2, the bonding wires 102h located at the corners of the semiconductor chip 100 are pulled up to a height H from the surfaces of the connection terminals 11 on the package substrate 10, and are connected to the bonding pads 101 (see FIG. 1). On the other hand, the bonding wires 102l are pulled up to a height L from the surfaces of the connection terminals 11, and are connected to the corresponding bonding pads 101. As explained above, the height H of the bonding wires 102h are set to be higher than those of the other bonding wires 102l. The heights of the four bonding wires 102h are substantially equal to each other. The semiconductor chip 100 is fixed to the package substrate 10 by a connection layer 110.

FIGS. 3A and 3B are partially cross-sectional views of FIG. 1; FIG. 3A is a cross-sectional view along a line A-A; and FIG. 3B is a cross-sectional view along a line B-B.

As shown in FIG. 3A, each boding wire 102h connects between the connection terminal 11 and the bonding pad 101, by having the height H from the surface of the connection terminal 11. As shown in FIG. 3B, each boding wire 102l connects between the connection terminal 11 and the bonding pad 101, by having the height L (L<H) from the surface of the connection terminal 11.

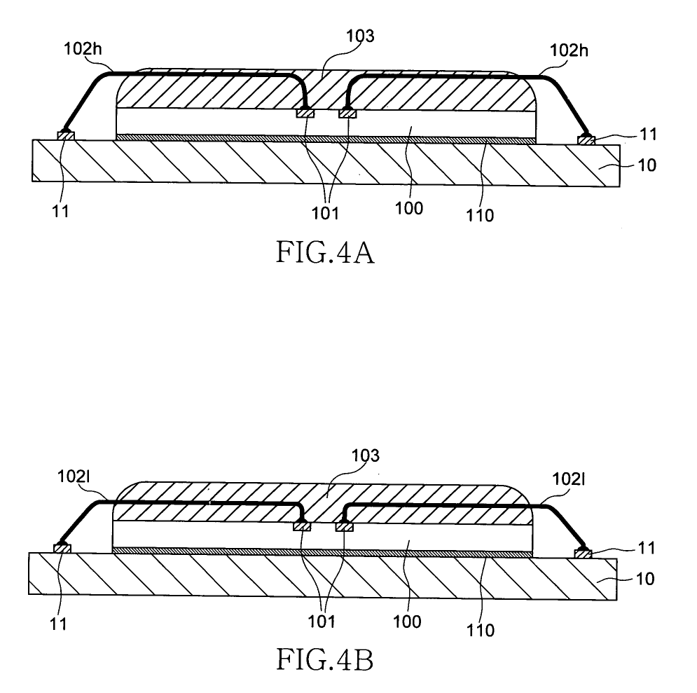

As described above, in the present embodiment, the four bonding wires 102h located at the corners are formed to have larger heights than other bonding wires among the plural bonding wires. A second-layer semiconductor chip is stacked on these bonding wires. A process from the lamination of the second-layer semiconductor chip till the completion of the semiconductor package by finally molding the whole is explained below with reference to FIGS. 4A and 4B to FIGS. 6A and 6B. FIGS. 4A, 5A and 6A correspond to the cross section along A-A in FIG. 1, and FIGS. 4B, 5B and 6B correspond to the cross section along B-B in FIG. 1.

First, as shown in FIGS. 4A and 4B, a liquid resin 103 is formed on the semiconductor chip 100 shown in FIG. 1 to fill a space between the bonding wires 102h, 102l and the surface of the semiconductor chip 100. When the liquid resin 103 is formed on the semiconductor chip 100, it forms a plane with the height substantially the same as that of the bonding wires 102h having the large height by the surface tension.

In other words, as shown in FIG. 4A, at the cross section A-A, the liquid resin 103 has the height substantially the same as that of the bonding wires 102h. Also, as shown in FIG. 4B, at the cross section B-B, the liquid resin 103 has the height equal to that of the cross section A-A, and is formed higher than the bonding wires 102l.

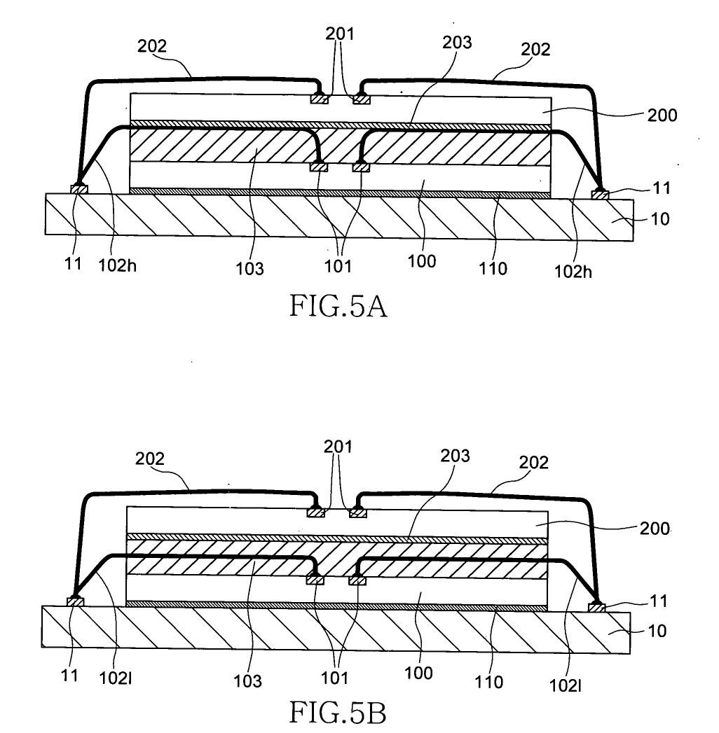

As shown in FIGS. 5A and 5B, a semiconductor chip 200 having a film-shaped resin 203 formed on the back surface is mounted on the liquid resin 103. Accordingly, the semiconductor chip 200 is stacked on the semiconductor chip 100 via the liquid resin 103 and the film-shaped resin 203. With this arrangement, the liquid resin 103 spreads to the total bottom surface of the semiconductor chip 200 (the film-shaped resin 203) according to the capillary phenomenon.

As shown in FIG. 5A, the semiconductor chip 200 is supported horizontally without an inclination, by the bonding wires 102h on the semiconductor chip 100. At this time, as shown in FIG. 5B, the bonding wires 102l are covered by the liquid resin 103, and are not brought into contact with the semiconductor chip 200 (the film-shaped resin 203). Thereafter, the liquid resin 103 is cured, and the semiconductor chip 200 is completely fixed.

Next, the bonding pads (the center pads) 201 provided on the surface of the semiconductor chip 200 and the connection terminals 11 on the package substrate 10 are connected by bonding wires 202, respectively. At this time, the semiconductor chip 200 is supported horizontally by the bonding wires 102h on the semiconductor chip 100. Therefore, even when bonding is performed on the semiconductor chip 200, concentration of the pressure to a part of the semiconductor chip 200 at the time of bonding can be prevented. Consequently, the risk that the bonding wires on the semiconductor chip 100 are pressed to be in contact with the semiconductor chip 100 can be prevented.

In the present embodiment, a further semiconductor layer is not stacked on the semiconductor chip 200. Therefore, none of the plural bonding wires 202 formed on the semiconductor chip 200 do not need to have a large height.

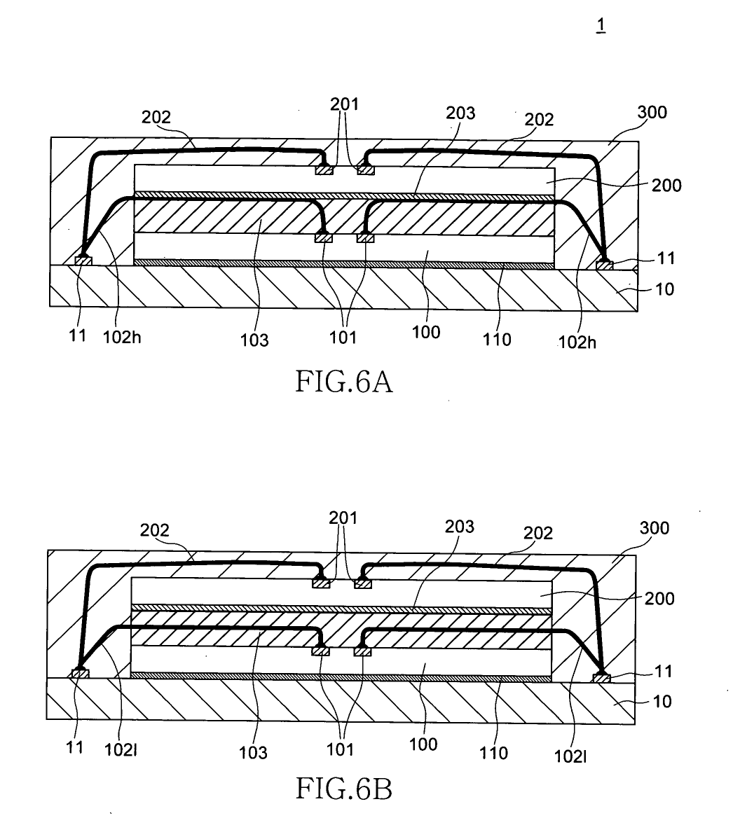

Last, as shown in FIGS. 6A and 6B, the total surface of the package substrate 10 is molded by a mold resin 300, thereby completing the semiconductor package 1.

As described above, according to the present embodiment, out of the plural bonding wires to be formed on the lower-layer semiconductor chip 100, the four bonding wires 102h laid out at the corners of the semiconductor chip 100 are formed higher than the other bonding wires 102l. The four bonding wires 102h are set to have substantially equal heights. Accordingly, the four bonding wires 102h have substantially the same large heights. Therefore, the upper-layer semiconductor chip 200 formed on the four bonding wires 102h are supported by these bonding wires 102h. Consequently, even when a variation occurs in the heights of the bonding wires 201l, the semiconductor chip 200 can be supported horizontally by the bonding wires 102h regardless of the variation in the heights of the bonding wires 102l. As a result, a contact between the bonding wires on the semiconductor chip 100 and the upper surface of the semiconductor chip 100 can be prevented.

Further, a supporting structure that supports the upper-layer semiconductor chip as required by the conventional technique does not need to be formed. Therefore, an additional manufacturing process is not necessary.

In the present embodiment, while the four boding wires 102h formed at the corners of the semiconductor chip 100 have large heights, the number of the boding wires 102h does not need to be four and can be at least three, when the upper-layer semiconductor chip 200 can be supported approximately horizontally. The high bonding wires are not necessarily required to be formed at the corners of the semiconductor chip 100, and can be formed at other suitable positions. However, when the bonding wires formed at the corners of the semiconductor chip 100 have large heights, the upper-layer semiconductor chip 200 can be supported more stably.

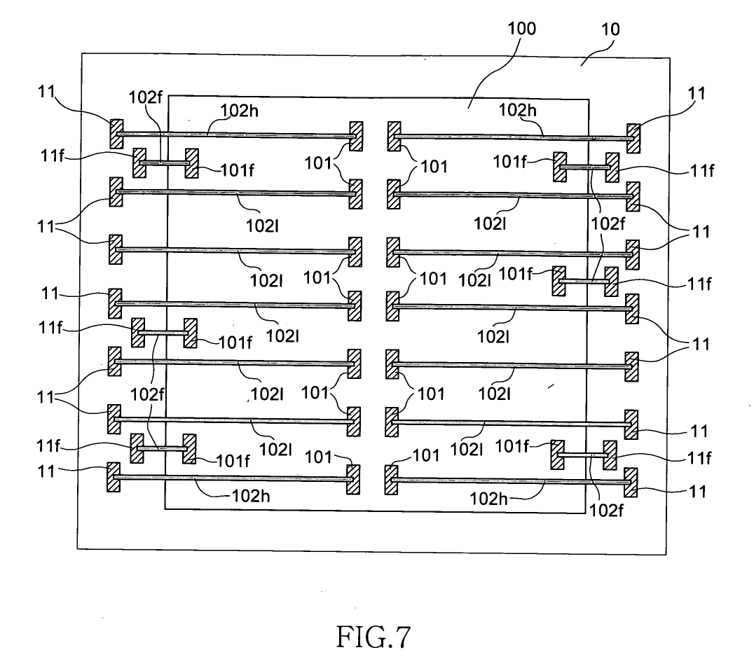

FIG. 7 is a plan view for explaining another embodiment of the present invention, and corresponds to the plan view in FIG. 1. In FIG. 7, Like reference numerals are designated to like parts in FIG. 1 and explanations thereof will be omitted.

As shown in FIG. 7, in the present embodiment, bonding pads (peripheral pads) 101f are also formed in areas other than the center area (the area where the center pads 101 are formed) of the surface of the semiconductor chip 100. The peripheral pads 101f are connected to connection terminals 11f formed on the package substrate 10, with bonding wires 102f, respectively.

When the supporting structure that supports the upper-layer semiconductor chip is formed on the periphery of the lower-layer semiconductor chip like in the above-described conventional technique, the supporting structure becomes a hindrance, and pads cannot be provided on the periphery. However, according to the present embodiment, bonding pads can be freely provided on the surface of the semiconductor chip 100.

Particularly, the electrode pads for power supply or for grounding are often laid out in the peripheral areas as well as in the center area of the semiconductor chip 100. Therefore, when the peripheral pads 101f are used like in the present modification, detour wiring of the power supply line and the ground line inside the semiconductor chip 100 can be avoided.

In the present embodiment, the bonding wires 102h at the corners of the semiconductor chip 100 can be also set high like in the above embodiment. Alternately, the bonding wires 102h can be formed at the same heights (L) as those of the bonding wires 102l, and at least three of the bonding wires 102f can be formed higher (the height: H).

Alternatively, at least three suitable bonding wires among the whole bonding wires 102h, 102l, and 102f can be selected and set to be higher than the other bonding wires. When it is easier to form the short bonding wires to be higher than long bonding wires because of the performance of a bonding device, for example, bonding wires to be set high can be selected from among the short bonding wires 102f. On the other hand, when it is easier to form the long bonding wires to be higher than short bonding wires, bonding wires to be set high can be selected from among the long bonding wires 102h and 102l.

While a preferred embodiment of the present invention has been described hereinbefore, the present invention is not limited to the aforementioned embodiment and various modifications can be made without departing from the spirit of the present invention. It goes without saying that such modifications are included in the scope of the present invention.

For example, the bonding wires to be formed high are not necessarily the ones that actually electrically connect between the semiconductor chip and the package substrate, and dummy wires can be used. The use of dummy wires is effective when the stress applied to the bonding wires 102h is large. When the stress applied to the bonding wires 102h is large, the bonding wires 102h to be formed high have a risk of being broken. However, when the dummy wires are used, damage given to the dummy wires has little influence to the actual operation, and reliability of the product can be increased.

In the present embodiment, while two semiconductor chips are stacked on the package substrate, three or more semiconductor chips can be also stacked. When three or more semiconductor chips are stacked, at least three bonding wires of each of other semiconductor chips than the top-layer semiconductor chip are formed high.

What is claimed is:

1. A semiconductor package comprising:
a package substrate on the surface of which a plurality of connection terminals are provided;
a first semiconductor chip on the surface of which a plurality of bonding pads are provided;
a plurality of bonding wires that connect between the plurality of connection terminals and the plurality of bonding pads, respectively;
a first resin formed to fill a gap between the plurality of bonding wires and the surface of the first semiconductor chip; and
a second semiconductor chip provided on the plurality of bonding wires via a film-shaped second resin, wherein
at least three of the plurality of bonding wires have substantially the same height and are higher than other bonding wires.

2. The semiconductor package as claimed in claim 1, wherein the plurality of bonding pads include a plurality of center pads laid out in a center area of the surface of the first semiconductor chip.

3. The semiconductor package as claimed in claim 1, wherein the plurality of bonding pads include peripheral pads laid out in areas other than the center area of the surface of the first semiconductor chip.

4. The semiconductor package as claimed in claim 1, wherein the at least three bonding wires are laid out at corners of the first semiconductor chip, respectively.

5. The semiconductor package as claimed in claim 1, wherein the at least three bonding wires are dummy wires.

6. The semiconductor package as claimed in claim 1, wherein the first resin is a cured liquid resin.

7. The semiconductor package as claimed in claim 1, wherein the surface of the first resin is substantially equal to the height of the at least three bonding wires.

8. The semiconductor package as claimed in claim 3, wherein the at least three bonding wires include at least one of bonding wires that connect between the peripheral pads and the connection terminals on the package substrate.

9. A semiconductor package comprising:
a first semiconductor chip on the surface of which first and second bonding pads are provided;
a second semiconductor chip stacked on the first semiconductor chip;
a resin provided between the first and second semiconductor chips; and
first and second bonding wires connected to the first and second bonding pads, respectively, wherein
an uppermost part of the first bonding wire is higher than that of the second bonding wire,
the uppermost part of the first bonding wire and upper surface of the resin are on the same level.

10. The semiconductor package as claimed in claim 9, wherein the first and second bonding pads are center pads laid out in a center area of the surface of the first semiconductor chip.

11. The semiconductor package as claimed in claim 9, wherein the first bonding wire includes at least three bonding wires.

12. The semiconductor package as claimed in claim 11, wherein the at least three bonding wires are laid out at corners of the first semiconductor chip, respectively.

13. A semiconductor package comprising:
a package substrate on the surface of which a plurality of connection terminals are provided;
a first semiconductor chip on the surface of which a plurality of bonding pads are provided;
a plurality of bonding wires that connect between the plurality of connection terminals and the plurality of bonding pads, respectively;
a resin formed to fill a gap between the plurality of bonding wires and the surface of the first semiconductor chip; and
a second semiconductor chip provided on the plurality of bonding wires, wherein
at least three of the plurality of bonding wires have substantially the same height and are higher than other bonding wires.

14. The semiconductor package as claimed in claim 13, wherein the plurality of bonding pads include a plurality of center pads laid out in a center area of the surface of the first semiconductor chip.

15. The semiconductor package as claimed in claim 13, wherein the plurality of bonding pads include peripheral pads laid out in areas other than the center area of the surface of the first semiconductor chip.

16. The semiconductor package as claimed in claim 13, wherein the at least three bonding wires are laid out at corners of the first semiconductor chip, respectively.

17. The semiconductor package as claimed in claim 13, wherein the at least three bonding wires are dummy wires.

18. The semiconductor package as claimed in claim 13, wherein the resin is a cured liquid resin.

19. The semiconductor package as claimed in claim 13, wherein the surface of the resin is substantially equal to the height of the at least three bonding wires.

20. The semiconductor package as claimed in claim 15, wherein the at least three bonding wires include at least one of bonding wires that connect between the peripheral pads and the connection terminals on the package substrate.
